(19) United States
(12) Patent Application Publication
(10) Pub. No.: US 2023/0298920 A1
(43) Pub. Date: Sep. 21, 2023

(54) ELECTROSTATIC CHUCK ASSEMBLY AND METHOD OF USING SAME

(71) Applicant: ASM IP Holding B.V., Almere (NL)

(72) Inventors: Sergei Golovkov, Tokyo (JP); Koji Tanaka, Tokyo (JP)

(21) Appl. No.: 18/120,752

(22) Filed: Mar. 13, 2023

Related U.S. Application Data
(60) Provisional application No. 63/320,436, filed on Mar. 16, 2022.

(51) Int. Cl. H01L 21/683; H01L 21/67; H01J 37/32

(52) U.S. Cl. CPC H01L 21/6833; H01L 21/67288; H01J 37/32724; H01J 2237/24564; H01J 2237/3321

(57) ABSTRACT

Electrostatic chuck assemblies, systems including the assemblies, and methods of using the electrostatic chuck assemblies and systems are disclosed. Exemplary electrostatic chuck assemblies include a detector or circuit to detect a chucking event, such as insufficient chucking power and/or substrate warpage. Exemplary systems and methods can adjust a chucking power based on the measured or determined chucking event.

### CROSS-REFERENCE TO RELATED APPLICATIONS

This application claims priority to U.S. Provisional Patent Application Ser. No. 63/320,436 filed Mar. 16, 2022 titled ELECTROSTATIC CHUCK ASSEMBLY AND METHOD OF USING SAME, the disclosure of which is hereby incorporated by reference in its entirety.

### FIELD OF INVENTION

The present disclosure generally relates to substrate processing apparatus and assemblies. More particularly, the disclosure relates to electrostatic chuck assemblies suitable for supporting substrates during gas-phase processes and to methods of using the assemblies.

### BACKGROUND OF THE DISCLOSURE

Electrostatic chucks can be used for a variety of applications. For example, an electrostatic chuck can be used to retain a substrate, such as a wafer, during a deposition and/or etch process.

A typical electrostatic chuck can include a ceramic body, one or more electrodes (e.g., an electrostatic and an RF electrode) embedded in the body, and a heating element or a plurality of heating elements embedded within the body. The electrostatic electrode can be used to provide an electrostatic force to retain the substrate in place during substrate processing.

From time to time, the electrostatic chuck may not function properly. For example, the electrostatic chuck may not provide a suitable chucking force to retain the substrate during processing or the electrostatic chuck may provide too much chucking force, which can result in damage to the substrate.

Some systems for determining chucking force exist. However, such systems may generally not be suitable for cyclical plasma-enhanced processes and/or for use with monopolar electrostatic chucks. Therefore, improved electrostatic chuck assemblies are desired.

Additionally or alternatively, it may be desirable to detect substrate warpage. Electrostatic chuck assemblies that can additionally or alternatively detect substrate warpage are therefore also desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to electrostatic chuck assemblies and to methods of using electrostatic chuck assemblies. While the ways in which various embodiments of the present disclosure address drawbacks of prior chuck assemblies and methods are discussed in more detail below, in general, exemplary chucks include components, such as current detectors, to determine whether a suitable or desired chucking event has occurred and/or whether an undesired chucking event and/or substrate warpage has been detected.

In accordance with exemplary embodiments of the disclosure, an electrostatic chuck assembly includes an electrostatic chuck comprising a body and an electrostatic electrode at least partially embedded within the body, an electrostatic chuck power supply electrically coupled to the electrostatic electrode, and a current detector electrically coupled between the electrostatic chuck power supply and the filter. The electrostatic chuck assembly can further include a filter interposed between the electrostatic chuck and the electrostatic chuck power supply and electrically coupled to the electrostatic chuck and the electrostatic chuck power supply. In accordance with examples of these embodiments, the current detector detects a leakage current. The leakage current can be indicative of a good or bad chucking event. The electrostatic chuck assembly can further include a heater at least partially embedded in the body. In accordance with further examples of these embodiments, the electrostatic chuck assembly can be used to characterize a chucking force at a beginning of a process step and/or during a process step.

In accordance with additional embodiments of the disclosure, an electrostatic chuck assembly includes an electrostatic chuck comprising a body and an electrostatic electrode at least partially embedded within the body, an electrostatic chuck power supply electrically coupled to the electrostatic electrode, and a detection circuit between the electrostatic electrode and the electrostatic chuck power supply. The detection circuit can include a high-frequency power source, a current measurement device, and a voltage measurement device. Such electrostatic chuck assembly can be used to detect a chucking status without a forming plasma and/or is suitable for use with monopolar electrostatic chucks. The high-frequency power source can provide power having a frequency less than 8 MHz or between about 1 kHz and about 2 MHz. The electrostatic chuck assembly can include an RF filter between the high-frequency power source and the detection circuit. The high-frequency power source can be a variable frequency power source. In some cases, a frequency of the variable frequency power can be manipulated to tune a sensitivity of the detection circuit.

In accordance with further exemplary embodiments of the disclosure, a plasma-enhanced deposition system including an electrostatic chuck assembly, as described herein, is provided. Exemplary plasma-enhanced deposition systems can include a controller configured to receive input from a detection circuit and control a voltage to the electrostatic electrode based on the input from the detection circuit or similar device.

In accordance with yet further embodiments of the disclosure, a method of determining warpage of a (e.g., processed) substrate is provided. An exemplary method includes providing a substrate on an electrostatic chuck comprising an electrostatic electrode, applying an electrostatic voltage to the electrostatic electrode, ceasing application of the electrostatic voltage to the electrostatic electrode, measuring a RC time constant of the electrostatic electrode, and comparing the RC time constant with a reference value.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a system including an electrostatic chuck assembly in accordance with examples of the disclosure.

FIG. 2 illustrates a portion of an electrostatic chuck assembly of FIG. 1 in greater detail and in accordance with at least one embodiment of the disclosure.

FIG. 3 illustrates current measurements associated with electrostatic chucking forces in accordance with at least one embodiment of the disclosure.

FIG. 4 illustrates another system including an electrostatic chuck assembly in accordance with examples of the disclosure.

FIG. 5 illustrates a portion of the electrostatic chuck assembly of FIG. 4 in greater detail and in accordance with at least one embodiment of the disclosure.

FIG. 6 illustrates another system including an electrostatic chuck assembly in accordance with examples of the disclosure.

FIG. 7 illustrates RC time constant measurements suitable for determining a chucking event in accordance with at least one embodiment of the disclosure.

FIG. 8 illustrates a warped substrate.

FIG. 9 illustrates a non-warped substrate.

FIG. 10 illustrates a gap between a substrate and a susceptor that can be characterized in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to electrostatic chuck assemblies and to methods of using the assemblies. The chuck assemblies and methods as described herein can be used in a variety of applications, such as deposition and/or etch processes, which can be used in the manufacture of electronic devices. By way of examples, the chuck assemblies and methods can be used in cyclical deposition and/or etch processes, such as plasma-enhanced atomic layer deposition and/or atomic layer etching.

As used herein, the term “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various topologies, such as recesses, lines, and the like formed within or on at least a portion of a layer of the substrate. In accordance with examples of the disclosure, the substrate includes a semiconductor wafer.

Further, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

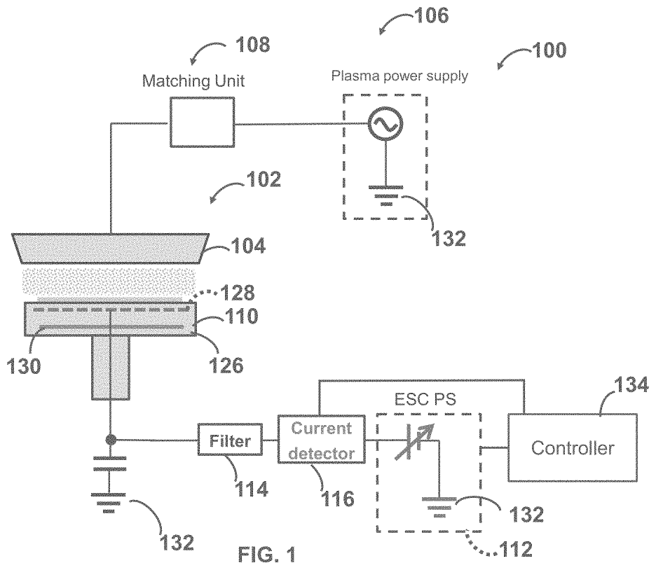

Turning now to the figures, FIG. 1 illustrates an exemplary system 100, which includes an electrostatic chuck assembly 102 in accordance with examples of the disclosure. System 100 can form part of a reactor system that can be used for a variety of applications, such as, for example, plasma-enhanced atomic layer deposition (PEALD) and/or plasma-enhanced atomic layer etching (PEALE).

In the illustrated example, system 100 includes chuck assembly 102, an upper electrode 104, a plasma power unit 106, and a plasma power matching unit 108. System 100 and/or assembly 102 can also include a controller 134.

Electrostatic chuck assembly 102 includes an electrostatic chuck 110, an electrostatic chuck power supply 112, a filter 114, and a current detector 116. System 100 can also include a heater 130.

In the illustrated example, electrostatic chuck 110 includes a body 126 and at least one electrostatic electrode 128 at least partially, and in some cases fully, embedded within body 126. Electrostatic chuck 110 also includes heater 130 at least partially embedded in body 126.

In the illustrated example, electrostatic chuck power supply 112 is electrically coupled to electrostatic electrode 128 and to ground 132. Electrostatic chuck power supply 112 can include any suitable power supply, such as 1000 V power supply.

Filter 114 can be or include any suitable filter, such as RC low-pass filter. Filter 114 is interposed between electrostatic chuck 110 and electrostatic chuck power supply 112 and is electrically coupled to electrostatic electrode 128 and electrostatic chuck power supply 112.

Plasma power supply 106 and matching unit 108 can include any suitable power supply and matching unit used in plasma deposition systems.

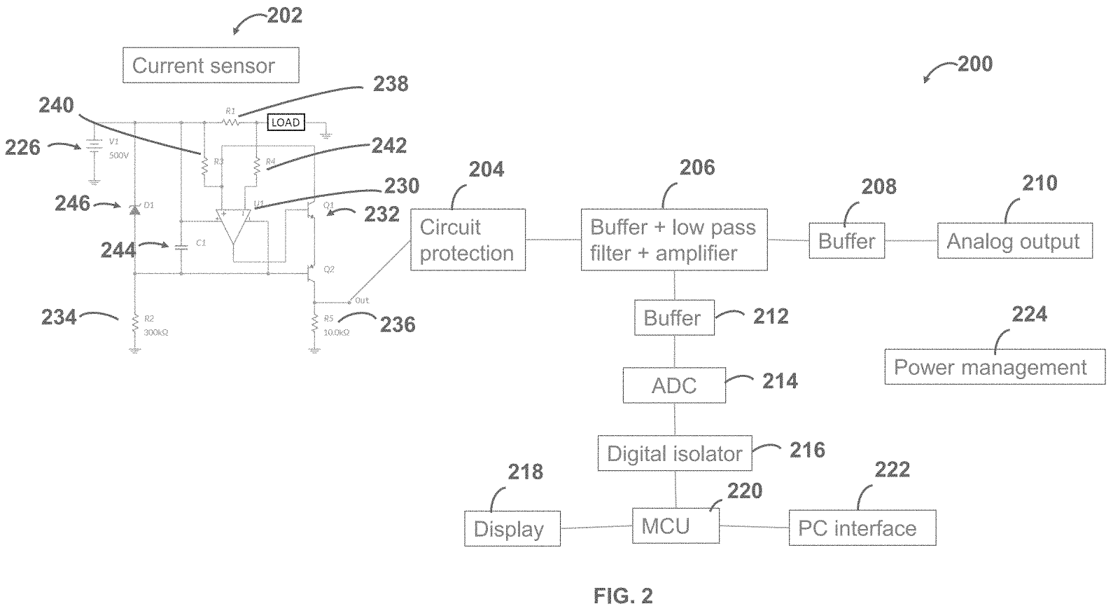

Current detector 116 is electrically coupled between electrostatic chuck power supply 112 and filter 114 or electrostatic electrode 128. Current detector 116 can be or include any suitable current detector, such as detector 200, illustrated in FIG. 2. In accordance with examples of the disclosure, current detector 116 detects or measures leakage current—e.g., during a process (e.g., deposition or etch) step.

With reference to FIG. 2, current detector 200/116 includes a current sensor 202, a current protection device 204, components 206, a buffer 208, an analog output 210, a buffer 212, an analog to digital converter 214, a digital isolator 216, optionally a display 218, a microcontroller unit (MCU) 220, a PC interface 222, and a power management system 224.

Current sensor 202 can include the illustrated circuit, which includes a voltage source 226, an amplifier 230, a transistors 232, resistors 234-242, capacitor 244, and Zener diode 246. Exemplary values of various components of sensor 202 are illustrated in FIG. 2. These values are merely exemplary and not necessarily limiting.

Current protection device 204 can include, for example a fuse and a TVS-diode.

Components 206 can include a buffer, a low-pass filter, and an amplifier. Buffers, including buffer 208 and 218, can include, for example, an operational amplifier with high-impedance input and low-impedance output. The low-pass filter can include, for example, a Sallen-Key low pass-filter.

Analog output 210 can be coupled to external data acquisition system.

Analog to digital converter 214 can include any suitable converter, such as an Analog Devices AD7134. Digital isolator can include any suitable isolator, such as an Analog Devices ADUM4151.

Display 218 and MCU 220 can form part of a computer or a controller, such as controller 134. PC interface 222 can be used to interface the computer with current detector 200. Power management 224 can be used to provide the power and/or voltage to current sensor 202 and/or other components of current detector 200.

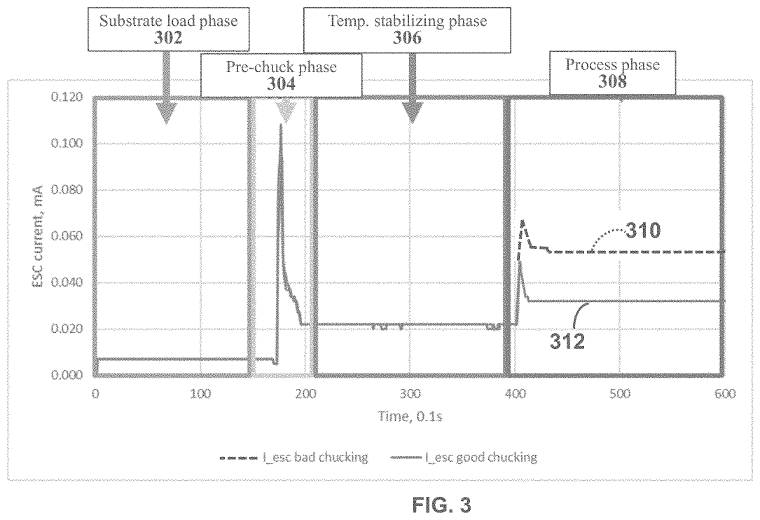

Controller 134 can be coupled to current detector 116 and electrostatic chuck power supply 112. Controller 134 can be configured to effect detection of leakage current between electrostatic electrode 128 and current detector 116 prior to a process cycle or during (e.g., at a beginning) of a process cycle, as illustrated in FIG. 3.

FIG. 3 illustrates current detected using current detector 116 while processing a substrate. In the illustrated example, the current is measured using current detector 116 during a substrate load phase 302, a pre-chuck phase 304, a temperature stabilizing phase 306, and/or a process phase 308. Dashed line 310 represents current measurements for a bad (e.g., non) chucking event and solid line 312 represents current measurements for a satisfactory chucking event. Particularly during process phase 308, current measurements can be compared to current measurements for known good chucking events and/or can be displayed to a user for determining whether a chucking event is satisfactory. The measured current can include current that includes leakage current from electrostatic electrode 128. In accordance with examples of the disclosure, the current measured using current detector 116 is typically less than 0.2 mA or between about 0.001 and about 0.12 mA.

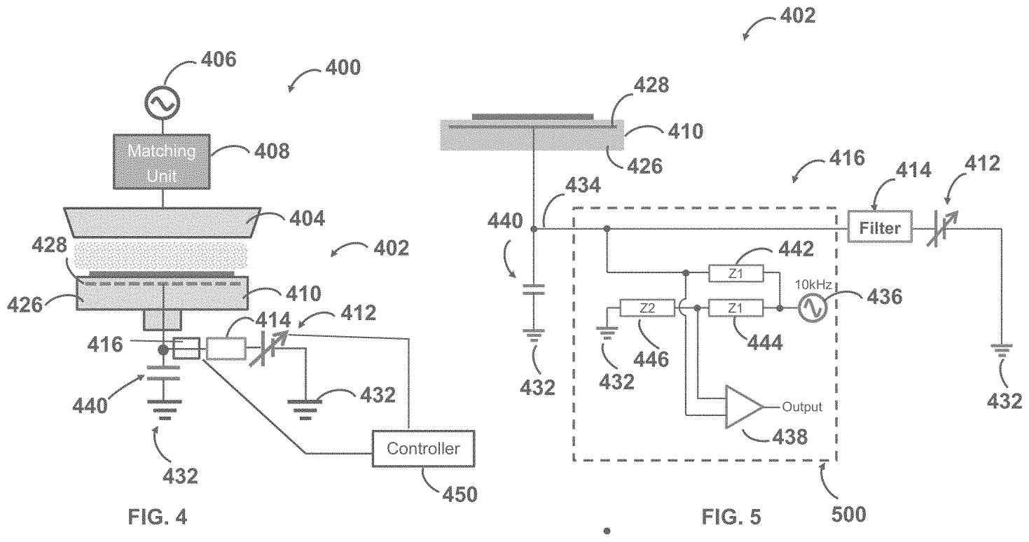

FIG. 4 illustrates another system 400 in accordance with examples of the disclosure. Similar to system 100, system 400 includes a chuck assembly 402, an upper electrode 404, a plasma power unit 406, and a plasma power matching unit 408. System 400 and/or assembly 402 can also include a controller 450. System 400 may be particularly useful to detect a chucking event or status for monopolar electrostatic chuck assemblies.

Electrostatic chuck assembly 402, includes an electrostatic chuck 410, an electrostatic chuck power supply 412, a filter 414, and a detection circuit 416.

In the illustrated example, electrostatic chuck 410 includes a body 426 and at least one electrostatic electrode 428 at least partially, and in some cases fully, embedded within body 426.

Electrostatic chuck power supply 412 is electrically coupled to electrostatic electrode 428 and to ground 432. Electrostatic chuck power supply 112 can include any suitable power supply, such as the power supplies described above.

Filter 414 can be or include any suitable filter, such as an RC low-pass filter. Filter 414 is interposed between electrostatic chuck 110 and electrostatic chuck power supply 412 and is electrically coupled to electrostatic chuck (e.g., electrode 428) and electrostatic chuck power supply 412 and/or between detection circuit 416 and electrostatic chuck power supply 412.

Detection circuit 416 is electrically coupled between electrostatic chuck power supply 412 and electrostatic electrode 428. Detection circuit 416 can be or include any suitable voltage detector, such as detector 500, illustrated in FIG. 5. In accordance with examples of the disclosure, detection circuit 416 applies a high-frequency power (e.g. 1 w) to a line 434 coupled to electrostatic electrode 428 and measures a current, voltage, and impedance on line 434 or between line 434 and ground 432.

System 400 includes a blocking capacitor 440 between electrostatic electrode 428 and ground 432. The purpose of the blocking capacitor(s) 440 is to prevent DC ground faults and ground the RF electrodes. Capacitance should be selected according to frequency to achieve low impedance to RF. A capacitance of 12 nF or more is generally required for 13 0.56 MHz to keep the impedance below 10.

Although wafer warpage changes the capacitance, the change in capacitance is relatively minute compared to the capacitance of a blocking capacitor 440. To improve sensitivity of detection circuit 416, circuit 416 is configured to cancel an influence of a load-side element. In the illustrated example, detection circuit 416/500 includes a high-frequency power source 436. High-frequency power source 436 can supply power at a frequency of less than 8 MHz or between about 1 kHz and about 2 MHz. High-frequency power source 436 can be a variable frequency power source. Sensitivity of circuit 416 can be manipulated by manipulating a frequency of power from high-frequency power source 436—e.g., using controller 450.

Detection circuit 416/500 further includes an amplifier 438 and impedances 442, 444 (Z1) and 446 (Z2). Impedance 442 is coupled between high-frequency power source 436 and the electrostatic electrode 428 and impedances 444 and 446 are coupled between high-frequency power source 436 and ground 432. By making Z2 equal to the load including the blocking capacitor 440, an effect of the load-side element can be canceled. By adjusting the ratio of Z1 to Z2, an input voltage to the amplifier can be adjusted.

Controller 450 can be coupled to detection circuit 416 and electrostatic chuck power supply 412. Controller 450 can be configured to effect detection of a chucking event—e.g., insufficient chucking—by comparing one or more of measured high-frequency current, high-frequency voltage and impedance. System 400 and controller 450 can automatically increase the applied voltage and stabilize the chucking force when the chucking force is determined to be insufficient. For example, controller 450 can be configured to receive input from the detection circuit 416 (e.g., from an output thereof) and send a control signal to control voltage to electrostatic chuck power supply 412 based on the input received from detection circuit 416. Electrostatic chuck power supply 412 can increase or decrease power to electrostatic electrode 428 based on the received control signal.

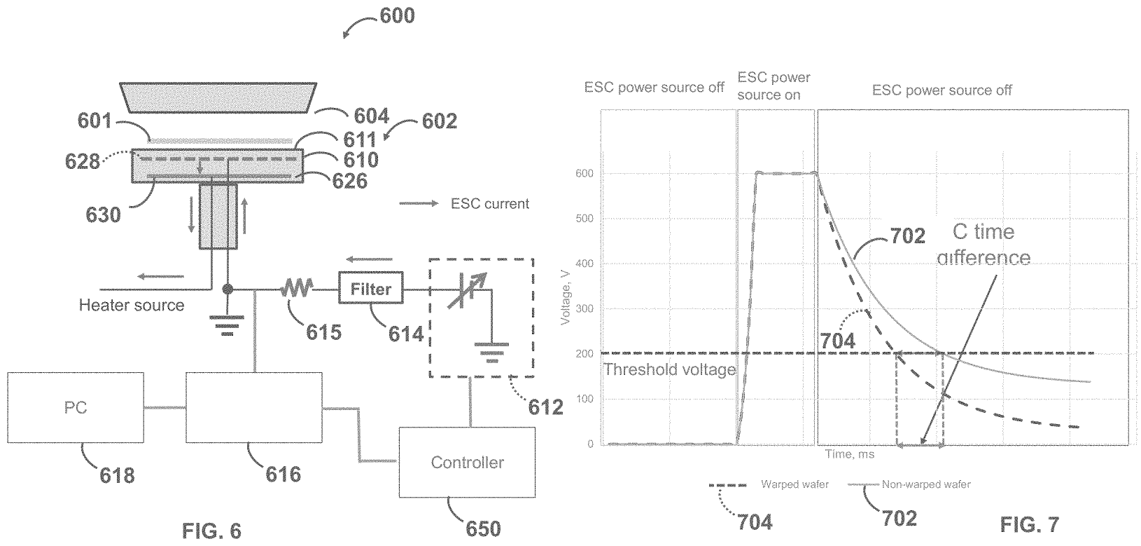

FIG. 6 illustrates another system 600 in accordance with additional examples of the disclosure. Similar to systems 100 and 400, system 600 includes a chuck assembly 602, an upper electrode 604, and can include a plasma power unit and a plasma power matching unit, as described above. System 600 and/or assembly 602 can also include a controller 650. System 600 may be particularly useful to detect or characterize a gap between a substrate 601 and a surface 611 of electrostatic chuck 610. By characterizing a gap between the substrate and the electrostatic chuck, a warpage of substrate 601 can be characterized.

Electrostatic chuck assembly 602 includes an electrostatic chuck 610, an electrostatic chuck power supply 612, a filter 614, an impedance 615, and a detection circuit 616. Although not separately illustrated, electrostatic chuck assembly 602 can also include a heater power supply.

In the illustrated example, electrostatic chuck 610 includes a body 626 and at least one electrostatic electrode 628 at least partially, and in some cases fully, embedded within body 626. Electrostatic chuck 610 can also include a heater 630, such as heater 130 (described above) at least partially embedded in body 626. In at least some cases, system 600 and chuck assembly 602 do not include a LRF module to provide low frequency to chuck 110.

Electrostatic chuck power supply 612 and filter 614 can be as described above in connection with FIG. 1. Impedance 615 can include a suitable impedance.

Detection circuit 616 can be or include a high-speed (e.g., over 10 kHz) voltage measurement device. The output from detection circuit 616 can be coupled to a computer 618 and/or to controller 650.

Controller 650 can be configured to apply voltage to the ESC electrode(s) 628 for a period of time (e.g., more than 0.1 seconds), cease application of a voltage from electrostatic chuck power supply, measure an RC time constant of electrostatic chuck discharging, and compare the measured RC time constant with reference data and stop or continue processing based on the comparison.

In accordance with further examples, a method is provided. An exemplary method includes providing a substrate on an electrostatic chuck comprising an electrostatic electrode, applying an electrostatic voltage to the electrostatic electrode (e.g., to initiate chucking), ceasing application of the electrostatic voltage to the electrostatic electrode (e.g., unclamping), measuring a RC time constant of the electrostatic electrode (e.g., using a high-voltage, high-speed voltmeter), and comparing the RC time constant with a reference value. Exemplary methods and/or controller functions can further include determining that a substrate is warped when a measured RC time constant is below a threshold value. Exemplary methods can further include providing a signal to indicate a warped substrate has been detected—e.g., to computer 618 or another wired or wirelessly-connected device. Exemplary methods can additionally or alternatively include a step of processing the substrate after the step of applying the electrostatic voltage to the electrostatic electrode and prior to the step of ceasing application of the electrostatic voltage to the electrostatic electrode.

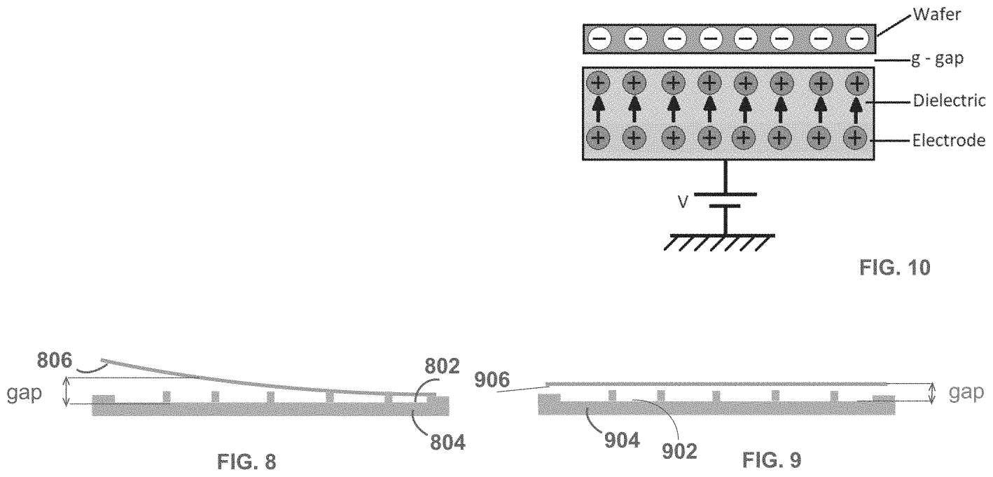

FIGS. 8-10 illustrate gap measurement using RC time constant determination and comparison techniques described herein.

RC=R_die×C_gap=ρ(dielectric)×ε_0×k_gx(d(dielectric))/gap
where ρ(dielectric) is the dielectric volume resistivity;
ε_0 is the free space permittivity;
k_g is the vacuum-gap dielectric constant;
d(dielectric) is the dielectric layer thickness; and
gap is the distance between a surface 802, 902 of a dielectric (ESC 804, 904) and a substrate surface 806, 906.

Generally, a measured RC time constant for a warped substrate will be less than an RC time constant for a non-warped substrate. Thus, warpage can be determined by comparing a measured RC time constant to an RC time constant of a known non-warped substrate or a known good value.

FIG. 7 illustrates RC time constant measurements for a non-warped substrate 702 and for a warped substrate 704. In accordance with examples of the disclosure, when an RC time constant difference between a measured RC time constant and a known good RC time constant is greater than a threshold value, controller 650 can increase a chucking force to chuck substrate 601.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements (e.g., steps) described, may become apparent to those skilled in the art from the description. Such modifications and embodiments are also intended to fall within the scope of the appended claims.

What is claimed is:

1. An electrostatic chuck assembly comprising:
an electrostatic chuck comprising a body and an electrostatic electrode at least partially embedded within the body;
an electrostatic chuck power supply electrically coupled to the electrostatic electrode;
a filter interposed between the electrostatic chuck and the electrostatic chuck power supply and electrically coupled to the electrostatic chuck and the electrostatic chuck power supply; and
a current detector electrically coupled between the electrostatic chuck power supply and the filter.

2. The electrostatic chuck assembly of claim 1, wherein the current detector detects leakage current.

3. The electrostatic chuck assembly of claim 1, further comprising a heater at least partially embedded in the body.

4. The electrostatic chuck assembly of claim 3, further comprising a current protection device.

5. The electrostatic chuck assembly of claim 1, further comprising a digital isolator.

6. The electrostatic chuck assembly of claim 4, further comprising a power management system.

7. The electrostatic chuck assembly of claim 1, further comprising a controller, the controller configured to effect detection of leakage current between the electrostatic electrode and the current detector prior to a process cycle.

8. A plasma-enhanced deposition system comprising the electrostatic chuck assembly of claim 1.

9. An electrostatic chuck assembly comprising:
an electrostatic chuck comprising a body and an electrostatic electrode at least partially embedded within the body;
an electrostatic chuck power supply electrically coupled to the electrostatic electrode; and
a detection circuit between the electrostatic electrode and the electrostatic chuck power supply, wherein the detection circuit comprises:
a high-frequency power source;
a current measurement device; and
a voltage measurement device.

10. The electrostatic chuck assembly of claim 9, further comprising a blocking capacitor between the detection circuit and ground.

11. The electrostatic chuck assembly of claim 9, wherein the high-frequency power source provides power having a frequency less than 8 MHz or between about 1 kHz and about 2 MHz.

12. The electrostatic chuck assembly of claim 9, wherein the detection circuit comprises an amplifier.

13. The electrostatic chuck assembly of claim 9, wherein the detection circuit comprises a first impedance coupled between the high-frequency power source and the electrostatic electrode and a second impedance coupled between the high-frequency power source and ground.

14. The electrostatic chuck assembly of claim 9, further comprising an RF filter between the electrostatic chuck power supply and the detection circuit.

15. The electrostatic chuck assembly of claim 9, wherein the high-frequency power source is a variable frequency power source.

16. A plasma-enhanced deposition system comprising the electrostatic chuck assembly of claim 9.

17. The plasma-enhanced deposition system of claim 16, further comprising a controller configured to receive input from the detection circuit and control voltage to the electrostatic electrode based on the input from the detection circuit.

18. A method of determining warpage of a processed substrate, the method comprising the steps of:
providing a substrate on an electrostatic chuck comprising an electrostatic electrode;
applying an electrostatic voltage to the electrostatic electrode;
ceasing application of the electrostatic voltage to the electrostatic electrode;
measuring a RC time constant of the electrostatic electrode; and
comparing the RC time constant with a reference value.

19. The method of claim 18, further comprising determining that a substrate is warped when a measured RC time constant is below a threshold value.

20. The method of claim 18, wherein the RC time constant is determined using a high-voltage, high-speed voltmeter.

21. The method of claim 18, further comprising providing a signal to indicate a warped substrate has been detected.

22. The method of claim 18, further comprising a step of processing the substrate after the step of applying the electrostatic voltage to the electrostatic electrode and prior to the step of ceasing application of the electrostatic voltage to the electrostatic electrode.
